(19) United States
(12) Patent Application Publication
(10) Pub. No.: US 2011/0199821 A1
(43) Pub. Date: Aug. 18, 2011

(54) POWER MANAGEMENT CHIP FURNISHED WITH VOLTAGE CONTROLLER

(75) Inventors: Young Suk Son, Daejeon-si (KR); Yong Sung Ahn, Ansan-si, Gyeonggi-do (KR); Hyun Ja Cho, Chungcheongbuk-do (KR); Hyung Seog Oh, Chungcheongbuk-do (KR); Dae Keun Han, Daejeon-si (KR)

(73) Assignee: SILICON WORKS CO., LTD, Daejeon-si (KR)

(21) Appl. No.: 13/124,825

(22) PCT Filed: Oct. 13, 2009
(86) PCT No.: PCT/KR09/05888

§ 371 Date: Apr. 18, 2011

(30) Foreign Application Priority Data
Nov. 6, 2008 (KR) 10-2008-0109999

(51) Int. Cl. G11C 16/06

(52) U.S. Cl. 365/185.2

(57) ABSTRACT

A power management IC includes a first IC having a boost converter IC which generates a second voltage using a first voltage supplied from an outside and supplies the second voltages to a charge pump, a reference voltage generation circuit, and an EEPROM; and a second IC configured to be inputted with a third voltage and a fourth voltage as outputs of the charge pump and output a fifth voltage and a sixth voltage. The second IC has a voltage regulator which regulates the third voltage and the fourth voltage or the fifth voltage and the sixth voltage and generates an eighth voltage and a ninth voltage as voltages required for programming operation or erasing operation of the EEPROM.

### BACKGROUND OF THE INVENTION

1. Field of the Invention

The present invention relates to a power management IC (integrated circuit), and more particularly, to a power management IC with a voltage regulator which is embedded with an EEPROM and supplies voltages required for programming operation or erasing operation of the EEPROM not by using a separate external voltage source or a high voltage generation circuit but by regulating voltages naturally generated in operation of a system, so that the number of outer terminals and the size of the power management IC can be decreased.

2. Description of the Related Art

In general, an active matrix type flat panel display system has a display cell section and a driving section. In the display cell section, pixel electrodes and thin film transistors are arranged in the form of a matrix. The driving section is composed of a system interface, a printed circuit board (PCB), a column drive IC and a row drive IC.

In the active matrix type flat panel display system, data, control signals and a first voltage VCC are transmitted to the PCB through the system interface. The data and the control signals are transmitted to a timing controller (TCON). The data and the control signals having passed through the TCON are used to drive the row drive IC and the column drive IC.

The outputs of the row drive IC and the column drive IC drive cells of a flat panel display. At this time, in order to drive the thin film transistors (TFTs) in the cells, high voltages and low voltages are required.

FIG. 1 is a block diagram of a conventional active matrix type flat panel display system.

Referring to FIG. 1, in an active matrix type flat panel display system, a first voltage VCC is supplied from a system interface 110. The first voltage VCC is converted into a second voltage VDD higher than the first voltage VCC, by a boost converter IC serving as a power management IC 140. The second voltage VDD is used as a supply voltage to a column drive IC 160 and is also used as a voltage for generating voltages VGH and VGL.

A charge pump 150 generates a third voltage VGH higher than the second voltage VDD and a fourth voltage VGL lower than the second voltage VDD, using the second voltage VDD. The third voltage VGH and the fourth voltage VGL generated in this way are used as supply voltages to a level shift IC 120.

The level shift IC 120 shifts the levels of signals to be transmitted from a TCON 130 to a row drive IC 170, to voltage levels at which TFTs 181 of display cells 180 can be driven. Voltages that are shifted and used to turn on or off the TFTs 181 are a fifth voltage VGH1 and a sixth voltage VGL1.

In this way, in the active matrix type flat panel display system, the voltages to be used in the system are generated through the power management IC 140 and the charge pump 150. These voltages are used in a state in which they are shifted to desired voltage levels depending upon desired data and control signals.

Recently, in consideration of economic efficiency due to the sizes of a package and a chip, a ‘2 chip—1 packaging’ method has been proposed, in which a power management IC is constituted by packaging a boost converter IC employing a low voltage process and a level shift IC employing a high voltage process in one chip.

FIG. 2 is a block diagram of a power management IC which is used in the conventional active matrix type flat panel display system.

Referring to FIG. 2, a power management IC 140, which is used in the conventional active matrix type flat panel display system, is composed of a boost converter IC 141 and a level shift IC 142. By packaging these two ICs in one chip in this way, the number of pads of the chip and the size of the chip can be decreased.

Also, a recently developed power management IC used in an active matrix type flat panel display system is embedded with an EEPROM (electrically erasable programmable ROM) in addition to the boost converter IC and the level shift IC. The EEPROM stores data by a floating gate structure formed in respective memory cells. The EEPROM executes data programming operation by inserting electrons into floating gates and data erasing operation by removing the electrons inserted into the floating gates.

In the case where, as described above, the EEPROM is embedded in the power management IC which is used in the active matrix type flat panel display system, voltages for the programming and erasing operation of the EEPROM are required. In the conventional art, these voltages are supplied from a separate external voltage source through the terminals of the boost converter IC which includes the EEPROM or are supplied from a high voltage generation circuit which is formed in the power management IC.

FIGS. 3 and 4 are block diagrams of power management ICs which are used in the conventional active matrix type flat panel display system and are embedded with an EEPROM.

Referring to FIGS. 3 and 4, it is to be appreciated that, in the conventional active matrix type flat panel display system, voltages required for programming and erasing operation of an EEPROM 141a are supplied through outer terminals 191 from a separate external voltage source 190 or through a high voltage generation circuit 143 which is formed in a power management IC 140.

In the case where voltages required for programming and erasing operation of an EEPROM are supplied through outer terminals from a separate external voltage source or through a high voltage generation circuit which is formed in a power management IC, as the number of pads increases, the size of the power management IC increases. Also, since the voltages should be supplied through the outer terminals of the power management IC, a problem is caused in that an IC should be added onto a PCB.

### SUMMARY OF THE INVENTION

Accordingly, the present invention has been made in an effort to solve the problems occurring in the related art, and an object of the present invention is to provide a power management IC with a voltage regulator which supplies voltages required for programming operation or erasing operation of an EEPROM not by using a separate external voltage source or a high voltage generation circuit but by regulating voltages naturally generated in operation of a system, so that the number of outer terminals and the size of the power management IC can be decreased.

In order to achieve the above object, according to one aspect of the present invention, there is provided a power management IC comprising a first IC having a boost converter IC which generates a second voltage using a first voltage supplied from an outside and supplies the second voltages to a charge pump, a reference voltage generation circuit, and an EEPROM; and a second IC configured to be inputted with a third voltage and a fourth voltage as outputs of the charge pump and output a fifth voltage and a sixth voltage, wherein the second IC has a voltage regulator which regulates the third voltage and the fourth voltage or the fifth voltage and the sixth voltage and generates an eighth voltage and a ninth voltage as voltages required for programming operation or erasing operation of the EEPROM.

In order to achieve the above object, according to another aspect of the present invention, there is provided a power management IC comprising a first IC having a boost converter IC which generates a second voltage using a first voltage supplied from an outside and supplies the second voltages to a charge pump, a reference voltage generation circuit, and an EEPROM; and a second IC configured to be inputted with a third voltage and a fourth voltage as outputs of the charge pump and output a fifth voltage and a sixth voltage, wherein the second IC has a first voltage regulator which regulates the third voltage and the fourth voltage or the fifth voltage and the sixth voltage and generates an eighth voltage as a voltage required for programming operation or erasing operation of the EEPROM, and wherein the first IC has a second voltage regulator which regulates the eighth voltage and generates a ninth voltage as a voltage required for programming operation or erasing operation of the EEPROM.

### BRIEF DESCRIPTION OF THE DRAWINGS

The above objects, and other features and advantages of the present invention will become more apparent after a reading of the following detailed description taken in conjunction with the drawings, in which:

FIG. 1 is a block diagram of a conventional active matrix type flat panel display system;

FIG. 2 is a block diagram of a power management IC which is used in the conventional active matrix type flat panel display system;

FIG. 3 is a block diagram of a power management IC which is used in the conventional active matrix type flat panel display system and is embedded with an EEPROM;

FIG. 4 is a block diagram of another power management IC which is used in the conventional active matrix type flat panel display system and is embedded with an EEPROM;

FIG. 5 is a block diagram showing the configuration of a power management IC with a voltage regulator in accordance with an embodiment of the present invention; and

FIG. 6 is a block diagram showing the configuration of a power management IC with a voltage regulator in accordance with another embodiment of the present invention.

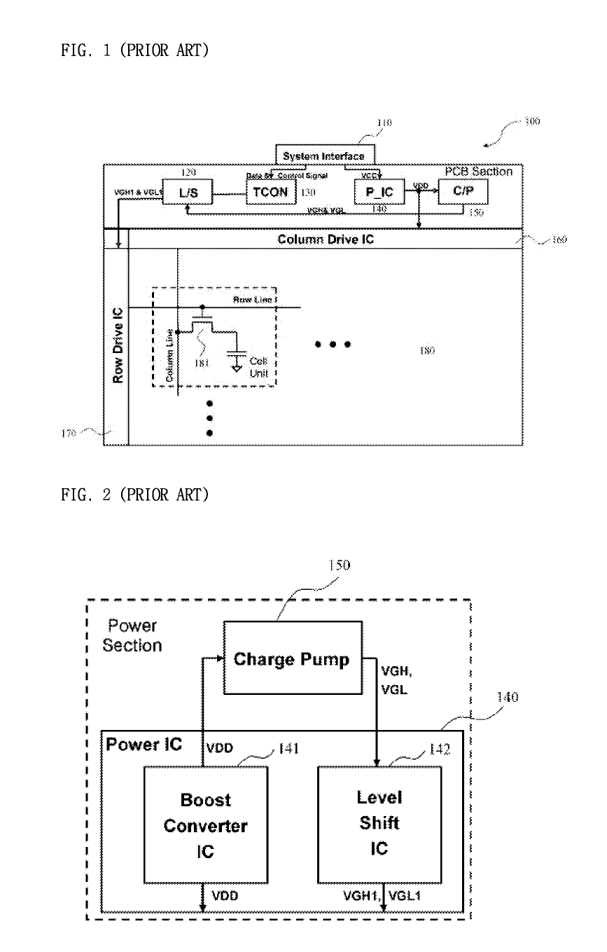

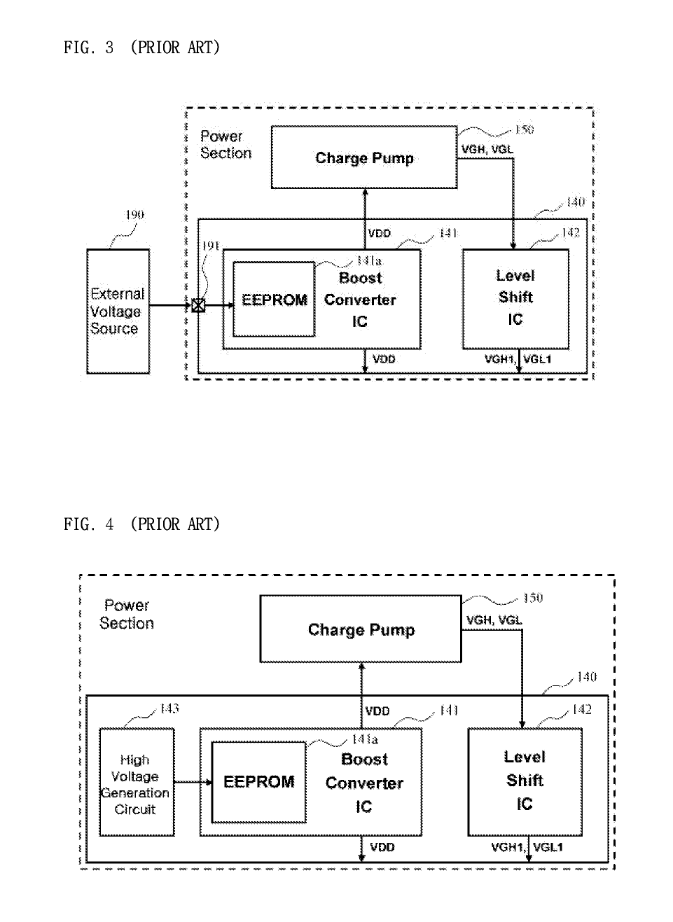

### DETAILED DESCRIPTION OF PREFERRED EMBODIMENTS

Reference will now be made in greater detail to preferred embodiments of the invention, examples of which are illustrated in the accompanying drawings. Wherever possible, the same reference numerals will be used throughout the drawings and the description to refer to the same or like parts.

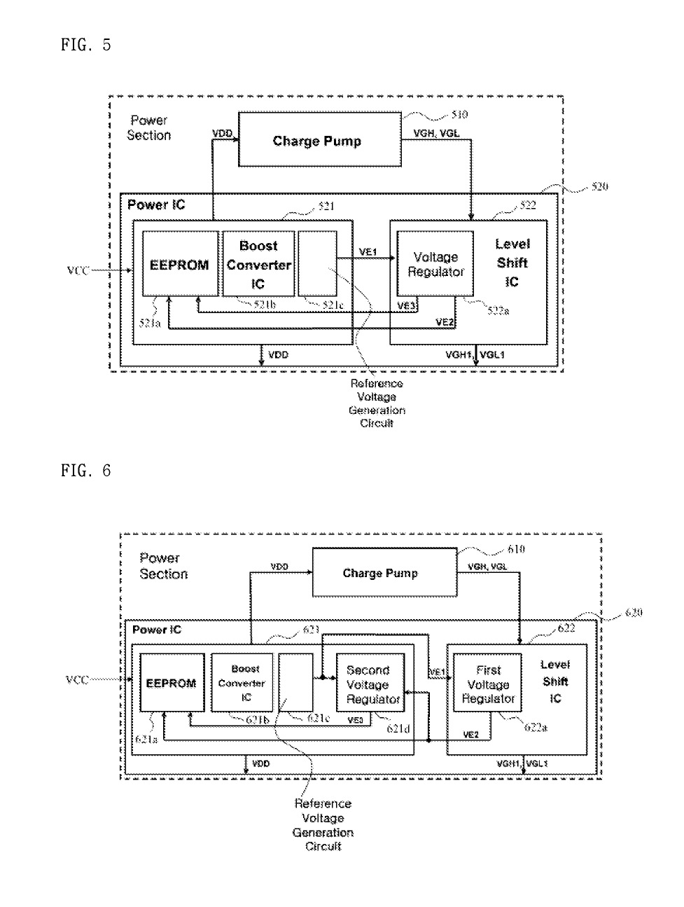

FIG. 5 is a block diagram showing the configuration of a power management IC with a voltage regulator in accordance with an embodiment of the present invention.

A power management IC 520 with a voltage regulator in accordance with an embodiment of the present invention includes a first IC 521 and a second IC 522.

The first IC 521 has an EEPROM 521a, a boost converter IC 521b and a reference voltage generation circuit 521c. The boost converter IC 521b generates a second voltage VDD using a first voltage VCC supplied from an outside and supplies the second voltage VDD to a charge pump 510. Since general operations of the reference voltage generation circuit 521c and the boost converter IC 521b are well known in the art, detailed description thereof will be omitted herein.

The charge pump 510 generates a third voltage VGH higher than the second voltage VDD and a fourth voltage VGL lower than the second voltage VDD, using the second voltage VDD. Since the operation of the charge pump 510 is well known in the art, detailed description thereof will be omitted herein.

The second IC 522 is inputted with the third voltage VGH and the fourth voltage VGL which are generated by the charge pump 510, and outputs a fifth voltage VGH1 and a sixth voltage VGL1 those are shifted to high levels. That is to say, the second IC 522 performs the function of a level shift IC. The fifth voltage VGH1 and the sixth voltage VGL1 are supplied to a row drive IC and are used to turn on or off thin film transistors (TFTs) (not shown) of a display cell section (not shown).

The second IC 522 further includes a voltage regulator 522a.

The voltage regulator 522a regulates the third voltage VGH, the fourth voltage VGL, the fifth voltage VGH1 and the sixth voltage VGL1 and generates an eighth voltage VE2 and a ninth voltage VE3 as voltages required for programming operation or erasing operation of the EEPROM 521a.

As a reference voltage used for regulating the voltages in the voltage regulator 522a, a seventh voltage VE1 as an output voltage of the reference voltage generation circuit 521c built in the first IC 521 is used.

FIG. 6 is a block diagram showing the configuration of a power management IC with a voltage regulator in accordance with another embodiment of the present invention.

A power management IC 620 with a voltage regulator in accordance with another embodiment of the present invention includes a first IC 621 and a second IC 622.

The first IC 621 has an EEPROM 621a, a boost converter IC 621b and a reference voltage generation circuit 621c. The boost converter IC 621b generates a second voltage VDD using a first voltage VCC supplied from an outside and supplies the second voltage VDD to a charge pump 610.

The charge pump 610 generates a third voltage VGH higher than the second voltage VDD and a fourth voltage VGL lower than the second voltage VDD, using the second voltage VDD. Since the operation of the charge pump 610 is well known in the art, detailed description thereof will be omitted herein.

The second IC 622 is inputted with the third voltage VGH and the fourth voltage VGL as outputs of the charge pump 610, and outputs a fifth voltage VGH1 and a sixth voltage VGL1 those are shifted to high levels.

The second IC 622 further includes a first voltage regulator 622a.

The first voltage regulator 622a regulates the third voltage VGH, the fourth voltage VGL, the fifth voltage VGH1 and the sixth voltage VGL1 and generates an eighth voltage VE2 as a voltage required for programming operation or erasing operation of the EEPROM 621a. As a reference voltage used for regulating the voltages in the first voltage regulator 622a, a seventh voltage VE1 as an output voltage of the reference voltage generation circuit 621c is used.

The first IC 621 further includes a second voltage regulator 621d.

The second voltage regulator 621d regulates the eighth voltage VE2 generated by the first voltage regulator 622a and generates a ninth voltage VE3 as a voltage required for the programming operation or the erasing operation of the EEPROM 621a. As a reference voltage used for regulating the voltage in the second voltage regulator 621d, the seventh voltage VE1 as the output voltage of the reference voltage generation circuit 621c is used.

Among the voltages required for the programming operation or the erasing operation of the EEPROM 621a, the eighth voltage VE2 generated by the first voltage regulator 622a is higher than the ninth voltage VE3 generated by the second voltage regulator 621d.

As described above, in the power management IC with a voltage regulator according to the present invention, voltages required for programming operation or erasing operation of the EEPROM are supplied by regulating the third voltage VGH, the fourth voltage VGL, the fifth voltage VGH1 and the sixth voltage VGL1 as voltages of various levels naturally generated in operation of the system.

Therefore, outer terminals for receiving the voltages required for the programming operation or erasing operation of the EEPROM from a separate external voltage source or a high voltage generation circuit is not needed, whereby the size of the power management IC can be decreased.

Although preferred embodiments of the present invention have been described for illustrative purposes, those skilled in the art will appreciate that various modifications, additions and substitutions are possible, without departing from the scope and the spirit of the invention as disclosed in the accompanying claims.

1. (canceled)

2. A power management IC comprising:
a first IC having a boost converter IC which generates a second voltage using a first voltage supplied from an outside and supplies the second voltages to a charge pump, a reference voltage generation circuit, and an EEPROM; and
a second IC configured to be inputted with a third voltage and a fourth voltage as outputs of the charge pump and output a fifth voltage and a sixth voltage,
wherein the second IC has a voltage regulator which regulates the third voltage and the fourth voltage or the fifth voltage and the sixth voltage by using a seventh voltage being an output voltage of the reference voltage generation circuit as a reference voltage and generates an eighth voltage and a ninth voltage as voltages required for programming operation or erasing operation of the EEPROM.

3. A power management IC comprising:
a first IC having a boost converter IC which generates a second voltage using a first voltage supplied from an outside and supplies the second voltages to a charge pump, a reference voltage generation circuit, and an EEPROM; and
a second IC configured to be inputted with a third voltage and a fourth voltage as outputs of the charge pump and output a fifth voltage and a sixth voltage,
wherein the second IC has a first voltage regulator which regulates the third voltage and the fourth voltage or the fifth voltage and the sixth voltage and generates an eighth voltage as a voltage required for programming operation or erasing operation of the EEPROM, and
wherein the first IC has a second voltage regulator which regulates the eighth voltage and generates a ninth voltage as a voltage required for programming operation or erasing operation of the EEPROM.

4. The power management IC according to claim 3, wherein the first voltage regulator generates the eighth voltage using a seventh voltage being an output voltage of the reference voltage generation circuit as a reference voltage, and the second voltage regulator generates the ninth voltage using the seventh voltage being the output voltage of the reference voltage generation circuit as a reference voltage.

5. The power management IC according to claim 2, wherein the second voltage generated by the boost converter IC is used to drive a column drive IC.

6. The power management IC according to claim 2, wherein the fifth voltage and the sixth voltage are supplied to a row drive IC and are used to turn on or off thin film transistors of display cells.

7. The power management IC according to claim 2, wherein the eighth voltage has a higher level than the ninth voltage.

8. The power management IC according to claim 4, wherein the second voltage generated by the boost converter IC is used to drive a column drive IC.

9. The power management IC according to claim 4, wherein the fifth voltage and the sixth voltage are supplied to a row drive IC and are used to turn on or off thin film transistors of display cells.

10. The power management IC according to claim 4, wherein the eighth voltage has a higher level than the ninth voltage.
